(19) United States
(12) Patent Application Publication
(10) Pub. No.: US 2026/0011295 A1
(43) Pub. Date: Jan. 8, 2026

(54) DISPLAY PANEL AND ELECTRONIC DEVICE HAVING THE SAME

(71) Applicant: Samsung Display Co., Ltd., Yongin-si (KR)

(72) Inventors: DONG-HOON LEE, Yongin-si (KR); ILNAM KIM, Yongin-si (KR); MINKYU WOO, Yongin-si (KR); JAEYONG JANG, Yongin-si (KR); MINJAE JEONG, Yongin-si (KR); JAEHYUNG CHO, Yongin-si (KR)

(21) Appl. No.: 19/249,890

(22) Filed: Jun. 25, 2025

(30) Foreign Application Priority Data
Jul. 3, 2024 (KR) 10-2024-0087271

(51) Int. Cl. G09G 3/32

(52) U.S. Cl. CPC G09G 3/32; G09G 2300/0426; G09G 2330/021

(57) ABSTRACT

Disclosed is a display panel including a first driving circuit including first stages arranged along a first direction, a second driving circuit including second stages arranged along the first direction, and at least one clock line between the first driving circuit and the second driving circuit, and extending along the first direction, wherein the first stages and the second stages include an oxide semiconductor transistor including an oxide semiconductor layer, and a gate electrode overlapping portions of the oxide semiconductor layer, and a conductive pattern adjacent to the oxide semiconductor transistor, and at a same layer as the gate electrode.

### CROSS-REFERENCE TO RELATED APPLICATION

The present application claims priority to, and the benefit of, Korean Patent Application No. 10-2024-0087271, filed on Jul. 3, 2024, in the Korean Intellectual Property Office, the entire disclosure of which is incorporated herein by reference.

### BACKGROUND

### 1. Field

Embodiments of the present disclosure described herein relate to a display panel, and an electronic device having the same, with reduced power consumption and improved display quality.

### 2. Description of the Related Art

Multimedia electronic devices, such as televisions, mobile phones, tablet computers, navigation systems, and game consoles, have a display device for displaying images. The display device includes a display panel and a driving part/driver. The display panel driver includes a scan driver that provides a scan signal to the plurality of scan lines, and a data driver that provides a data voltage to data lines.

### SUMMARY

Embodiments of the present disclosure provide a display panel, and electronic device having the same, with reduced power consumption and improved display quality.

According to one or more embodiments, a display panel includes a first driving circuit including first stages arranged along a first direction, a second driving circuit including second stages arranged along the first direction, and at least one clock line between the first driving circuit and the second driving circuit, and extending along the first direction, wherein the first stages and the second stages include an oxide semiconductor transistor including an oxide semiconductor layer, and a gate electrode overlapping portions of the oxide semiconductor layer, and a conductive pattern adjacent to the oxide semiconductor transistor, and at a same layer as the gate electrode.

The oxide semiconductor layer may include a first area, an active area, and a second area spaced apart from the first area with the active area therebetween, wherein the display panel further includes a first signal electrode electrically connected to the first area, and a second signal electrode electrically connected to the second area.

The conductive pattern may include an electrically floated island shape.

The conductive pattern may partially surround at least a portion of the first area in plan view.

The conductive pattern may be electrically connected to the second signal electrode.

The second signal electrode may include a first signal pattern electrically connected to one end of, and at a different layer from, the conductive pattern, and a second signal pattern spaced from the first signal pattern, and electrically connected to an opposite end of, and at a different layer from, the conductive pattern.

The conductive pattern may entirely overlap the second signal electrode in plan view.

The at least one clock line may include a first clock line, and a second clock line spaced apart from the first clock line in a second direction crossing the first direction.

The display panel may further include a dummy semiconductor pattern at a different layer from the oxide semiconductor layer, and an intermediate insulation layer covering the dummy semiconductor pattern, and defining a dummy through-hole adjacent to the oxide semiconductor layer and exposing at least a portion of the dummy semiconductor pattern.

The dummy semiconductor pattern may include a low-temperature poly silicon semiconductor.

The oxide semiconductor layer may be above the intermediate insulation layer.

The dummy semiconductor pattern may be provided in plural, the dummy semiconductor patterns being spaced apart along the first direction.

The dummy semiconductor patterns may be between the first clock line and the second clock line in plan view.

The conductive pattern may include titanium.

According to one or more embodiments, an electronic device includes a display panel and a processor that drives the display panel, the display panel including pixels, a first driving circuit electrically connected to the pixels, and including a first stage, a second driving circuit electrically connected to the pixels, and including a second stage, and a dummy semiconductor pattern between the first stage and the second stage in plan view, wherein the first stage and the second stage include an oxide semiconductor transistor including an oxide semiconductor layer and a gate electrode, and a conductive pattern, and wherein the conductive pattern and the dummy semiconductor pattern are adjacent to the oxide semiconductor layer in plan view.

The electronic device may further include an intermediate insulation layer covering the dummy semiconductor pattern, and defining a dummy through-hole adjacent to the oxide semiconductor layer and exposing at least a portion of the dummy semiconductor pattern, wherein the dummy semiconductor pattern includes a low-temperature poly silicon semiconductor, and wherein the oxide semiconductor layer is above the intermediate insulation layer.

The conductive pattern may include an electrically floated island shape, and may partially surround at least a portion of the oxide semiconductor layer in plan view.

The oxide semiconductor layer may include a first area, an active area, and a second area spaced apart from the first area with the active area therebetween, wherein the display panel further includes a first signal electrode electrically connected to the first area, and a second signal electrode electrically connected to the second area and electrically connected to the conductive pattern.

The second signal electrode may include a first signal pattern electrically connected to one end of the conductive pattern, and at a different layer from the conductive pattern, and a second signal pattern electrically connected to an opposite end of the conductive pattern, spaced from the first signal pattern, and at a different layer from the conductive pattern.

The conductive pattern may entirely overlap the second signal electrode in plan view.

### BRIEF DESCRIPTION OF THE DRAWING

The above and other aspects of the present disclosure will become apparent by describing in detail embodiments thereof with reference to the accompanying drawings.

FIG. 1 is a block diagram of an electronic device according to one or more embodiments of the present disclosure.

FIG. 2 is a circuit diagram of a pixel according to one or more embodiments of the present disclosure.

FIG. 3 is a cross-sectional view of a display panel according to one or more embodiments of the present disclosure.

FIG. 4 is a block diagram of a display panel according to one or more embodiments of the present disclosure.

FIG. 5 is a circuit diagram of a (1-1)-th stage according to one or more embodiments of the present disclosure.

FIG. 6 is an enlarged plan view of a portion of a display panel according to one or more embodiments of the present disclosure.

FIG. 7 is a cross-sectional view of a display panel taken along the line I-I′ of FIG. 6 according to one or more embodiments of the present disclosure.

FIG. 8 is an enlarged plan view of a portion of a display panel according to one or more embodiments of the present disclosure.

FIG. 9 is a cross-sectional view of a display panel taken along the line II-II′ of FIG. 8 according to one or more embodiments of the present disclosure.

FIG. 10 is a cross-sectional view of a display panel taken along the line II-II′ of FIG. 8 according to one or more embodiments of the present disclosure.

FIG. 11 is a block diagram of an electronic device according to one or more embodiments of the present disclosure.

FIG. 12 is a schematic diagram of an electronic device according to various embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group comprising X, Y, and Z,” and “at least one selected from the group comprising X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and

similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices, such as field programmable gate arrays (FPGAs).

Software components may indicate data used by executable codes and/or executable codes in a storage medium which is able to be addressed. Accordingly, software components may be, for example, object-oriented software components, class components, and task components, and may include processes, functions, properties, procedures, subroutines, program code segments, drivers, firmware, microcodes, circuits, data, database, data structures, tables, arrangements or variables. Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

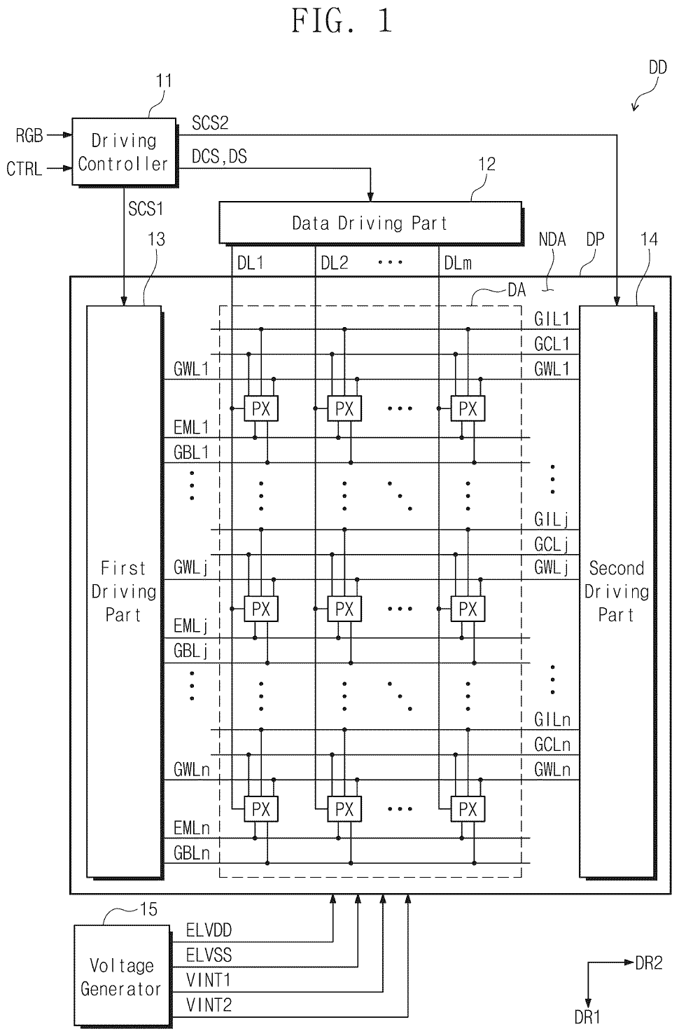

FIG. 1 is a block diagram of an electronic device DD according to one or more embodiments of the present disclosure.

Referring to FIG. 1, the electronic device DD may include a display panel DP, a driving controller 11, a data driver (e.g., data driving part) 12, a first driver (e.g., first driving part) 13, a second driver (e.g., second driving part) 14, and a voltage generator 15. The electronic device DD according to one or more embodiments of the present disclosure may be a portable terminal, such as a smart phone, a tablet PC, a personal digital assistant (PDA), a portable multimedia player (PMP), a game console, a wristwatch-type electronic device, and the like. However, the present disclosure is not limited thereto. The electronic device DD of the present disclosure may be used in large electronic equipment, such as small and medium-sized electronic equipment, such as personal computers, notebook computers, kiosks, car navigation units, and cameras, including large-sized electronic equipment, such as televisions or outdoor billboards. They are merely examples, and it is apparent that they may be applied to other electronic devices as long as they do not deviate from the concept of the present disclosure.

The display panel DP may include a display area DA and a non-display area NDA.

The driving controller 11 receives an input signal including an input image signal RGB and a control signal CTRL. The driving controller 11 generates an output image signal DS that is obtained by converting a data format of the input image signal RGB such that the output image signal DS matches the interface specification with the data driver 12. The driving controller 11 may drive the display panel DP and output a first scan control signal SCS1, a second scan control signal SCS2, and a data control signal DCS for performing a control such that an image is displayed on the display panel DP.

The data driver 12 receives a data control signal DCS and an output image signal DS from the driving controller 11. The data driver 12 converts the output image signal DS into data signals, and outputs the data signals to a plurality of data lines DL1 to DLm that will be described below. The data signals are analog voltages corresponding to grayscale values of the output image signal DS.

The display panel DP includes scan lines GIL1 to GILn, GCL1 to GCLn, GWL1 to GWLn, and GBL1 to GBLn, light emission control lines EML1 to EMLn, data lines DL1 to DLm, and pixels PX. The display panel DP may include a first driver 13 and a second driver 14. In one or more embodiments, the first driver 13 may be arranged on a first side of the display panel DP, and the second driver 14 may be arranged on a second side of the display panel DP.

The scan lines GIL1 to GILn, GCL1 to GCLn, GWL1 to GWLn, and GBL1 to GBLn may be referred to as initialization scan lines GIL1 to GILn, compensation scan lines GCL1 to GCLn, write scan lines GWL1 to GWLn, and black scan lines GBL1 to GBLn, respectively.

The black scan lines GBL1 to GBLn and the light emission control lines EML1 to EMLn may be electrically connected to the first driver 13. The initialization scan lines GIL1 to GILn and the compensation scan lines GCL1 to GCLn may be electrically connected to the second driver 14. Furthermore, the write scan lines GWL1 to GWLn may be electrically connected to the first driver 13 and the second driver 14.

Data lines DL1 to DLm extend from the data driver 12 in a first direction DR1 and are arranged spaced apart from each other in a second direction DR2.

In the example illustrated in FIG. 1, the first driver 13 and the second driver 14 are arranged to face each other in a non-display area NDA with a display area DA being interposed therebetween, but the present disclosure is not limited thereto. In one or more other embodiments, the first driver 13 and the second driver 14 may be arranged in the display area DA, and the display panel DP may include only one of the first driver 13 or the second driver 14.

The plurality of pixels PX are electrically connected to the initialization scan lines GIL1 to GILn, the compensation scan lines GCL1 to GCLn, the write scan lines GWL1 to GWLn, the black scan lines GBL1 to GBLn, the light emission control lines EML1 to EMLn, and the data lines DL1 to DLm, respectively. Each of the plurality of pixels PX may be electrically connected to four scan lines and one light emission control line. For example, as illustrated in FIG. 1, the pixels in a first row may be connected to the scan lines GIL1, GCL1, GWL1, and GBL1 and the light emission control line EML1. Furthermore, the pixels in a j-th row may be connected to the scan lines GILj, GCLj, GWLj, and GBLj and the light emission control line EMLj.

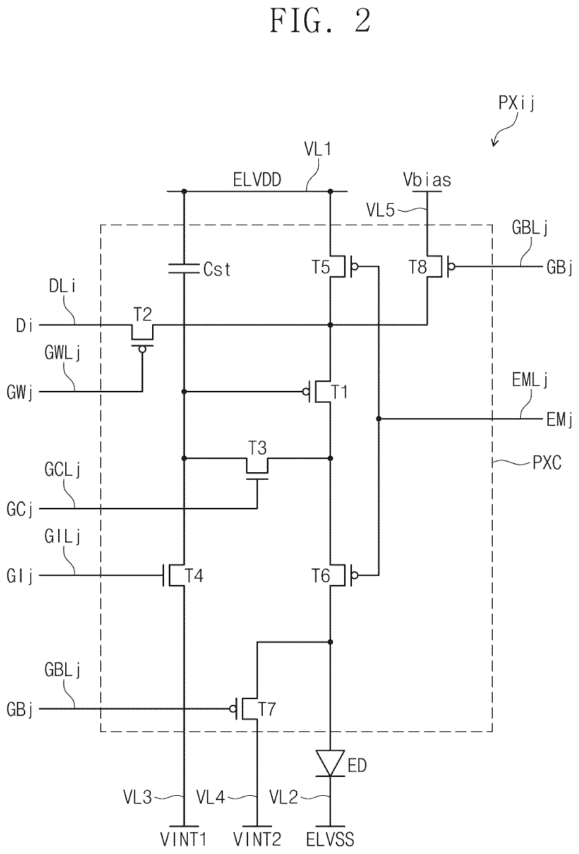

Each of the plurality of pixels PX includes a light-emitting element ED (see FIG. 2) and a pixel circuit PXC (see FIG. 2) that controls the light emission of the light-emitting element ED. The pixel circuit PXC may include one or more transistors and one or more capacitors. The first driver 13 and the second driver 14 may include transistors that are formed through the same process as that of a pixel circuit PXC.

The voltage generator 15 generates voltages that are required for an operation of the display panel DP. The voltage generator 15 generates a first driving voltage ELVDD, a second driving voltage ELVSS, a first initialization voltage VINT1, and a second initialization voltage VINT2.

Each of the plurality of pixels PX receives a first driving voltage ELVDD, a second driving voltage ELVSS, a first initialization voltage VINT1, and a second initialization voltage VINT2.

The first driver 13 receives a first scan control signal SCS1 from the driving controller 11. The first driver 13 may output scan signals to the write scan lines GWL1 to GWLn and black scan lines GBL1 to GBLn in response to the first scan control signal SCS1, and may output light emission signals to light emission control lines EML1 to EMLn.

The second driver 14 receives a second scan control signal SCS2 from the driving controller 11. The second driver 14 may output scan signals to the initialization scan lines GIL1 to GILn, the compensation scan lines GCL1 to GCLn, and write scan lines GWL1 to GWLn in response to the second scan control signal SCS2.

FIG. 2 is a circuit diagram of a pixel PXij according to one or more embodiments of the present disclosure.

FIG. 2 illustrates, by way of example, an equivalent circuit diagram of a pixel PXij that is connected to an i-th data line DLi, a j-th initialization scan line GILj, a j-th compensation scan line GCLj, a j-th write scan line GWLj, a j-th black scan line GBLj, and a j-th light emission control line EMLj in FIG. 1.

Each of the plurality of pixels PX illustrated in FIG. 1 may have the same circuit configuration as that of an equivalent circuit diagram of the pixel PXij illustrated in FIG. 2. A pixel circuit PXC of the pixel PXij includes first to eighth transistors T1, T2, T3, T4, T5, T6, T7, and T8, a capacitor Cst, and at least one light-emitting element ED. The light-emitting element ED may be a light-emitting diode.

Among the first to eighth transistors T1 to T8, the third and fourth transistors T3 and T4 may be N-type transistors having an oxide semiconductor as a semiconductor layer, and each of the first, second, fifth, sixth, seventh, and eighth transistors T1, T2, T5, T6, T7, and T8 may be a P-type transistor having a low-temperature polycrystalline silicon (LTPS) as a semiconductor layer. However, the present disclosure is not limited thereto, and all of the first to eighth transistors T1 to T8 may be P-type transistors or N-type transistors. In one or more other embodiments, at least one of the first to eighth transistors T1 to T8 may be an N-type transistor, and the remaining one or more may be P-type transistors.

The initialization scan line GILj may transmit an initialization scan signal Glj, the compensation scan line GCLj may transmit a compensation scan signal GCj, the write scan line GWLj may transmit a write scan signal GWj, and the black scan line GBLj may transmit a black scan signal GBj. The light emission control line EMLj may transmit a light emission signal EMj. The data line DLi may transmit a data signal Di. The data signal Di may have a voltage level corresponding to that of the input image signal RGB that is input to the electronic device DD (see FIG. 1). The first to fifth driving voltage lines VL1, VL2, VL3, VL4, and VL5 may respectively transmit a first driving voltage ELVDD, a second driving voltage ELVSS, a first initialization voltage VINT1, a second initialization voltage VINT2, and a bias voltage Vbias.

The first transistor T1 includes a first electrode that is connected to a first driving voltage line VL1 via a fifth transistor T5, a second electrode that is electrically connected to an anode of a light-emitting element ED via a sixth transistor T6, and a gate electrode that is connected to one end of a capacitor Cst. The first transistor T1 may receive a data signal Di transmitted by the data line DLi according to a switching operation of the second transistor T2 and may supply a driving current to the light-emitting element ED.

The second transistor T2 includes a first electrode that is connected to the data line DLi, a second electrode that is connected to the first electrode of the first transistor T1, and a gate electrode that is connected to the write scan line GWLj. The second transistor T2 is turned on according to a write scan signal GWj received through the write scan line GWLj and may transmit a data signal Di transmitted from the data line DLi to the first electrode of the first transistor T1.

The third transistor T3 includes a first electrode that is connected to the gate electrode of the first transistor T1, a second electrode that is connected to the second electrode of the first transistor T1, and a gate electrode that is connected to the compensation scan line GCLj. The third transistor T3 may be turned on according to a compensation scan signal GCj received through the compensation scan line GCLj and may diode-connect the first transistor T1 by connecting the gate electrode and the second electrode of the first transistor T1.

The fourth transistor T4 includes a first electrode that is connected to the gate electrode of the first transistor T1, a second electrode that is connected to the third voltage line VL3, to which a first initialization voltage VINT1 is transmitted, and a gate electrode that is connected to the initialization scan line GILj. The fourth transistor T4 may be turned on according to the initialization scan signal Glj transmitted through the initialization scan line GILj to transmit the first initialization voltage VINT1 to the gate electrode of the first transistor T1 to perform an initialization operation of initializing a voltage of the gate electrode of the first transistor T1.

The fifth transistor T5 includes a first electrode that is connected to the first driving voltage line VL1, a second electrode that is connected to the first electrode of the first transistor T1, and a gate electrode that is connected to a light emission control line EMLj.

The sixth transistor T6 includes a first electrode that is connected to the second electrode of the first transistor T1, a second electrode that is connected to the anode of the light-emitting element ED, and a gate electrode that is connected to the light emission control line EMLj.

The fifth transistor T5 and the sixth transistor T6 may be concurrently or substantially simultaneously turned on according to the light emission signal EMj transmitted through the light emission control line EMLj, and through this, the first driving voltage ELVDD may be compensated through the diode-connected first transistor T1 and transmitted to the light-emitting element ED.

The seventh transistor T7 includes a first electrode that is connected to the anode of the light-emitting element ED, a second electrode that is connected to the fourth voltage line VL4, and a gate electrode that is connected to the black scan line GBLj. The seventh transistor T7 is turned on according to a black scan signal GBj transmitted through the black scan line GBLj, and bypasses a current of the anode of the light-emitting element ED to the fourth voltage line VL4.

The eighth transistor T8 includes a first electrode that is connected to the fifth driving voltage line VL5, a second electrode that is connected to the first electrode of the first transistor T1, and a gate electrode that is connected to the black scan line GBLj. The eighth transistor T8 may be turned on according to the black scan signal GBj transmitted through the black scan line GBLj, and through this, the bias voltage Vbias may be compensated through the diode-connected first transistor T1 and transmitted to the light-emitting element ED.

As described above, one end of the capacitor Cst is connected to the gate electrode of the first transistor T1, and an opposite end thereof is connected to the first driving voltage line VL1. The anode of the light-emitting element ED may be connected to the second electrode of the sixth transistor T6, and the cathode may be connected to the second driving voltage line VL2 that transmits the second driving voltage ELVSS.

A circuit configuration of the pixel PXij according to one or more embodiments is not limited to FIG. 2. The number of transistors and the number of capacitors and the connection relationship thereof included in the pixel circuit PXC in the pixel PXij may be variously modified.

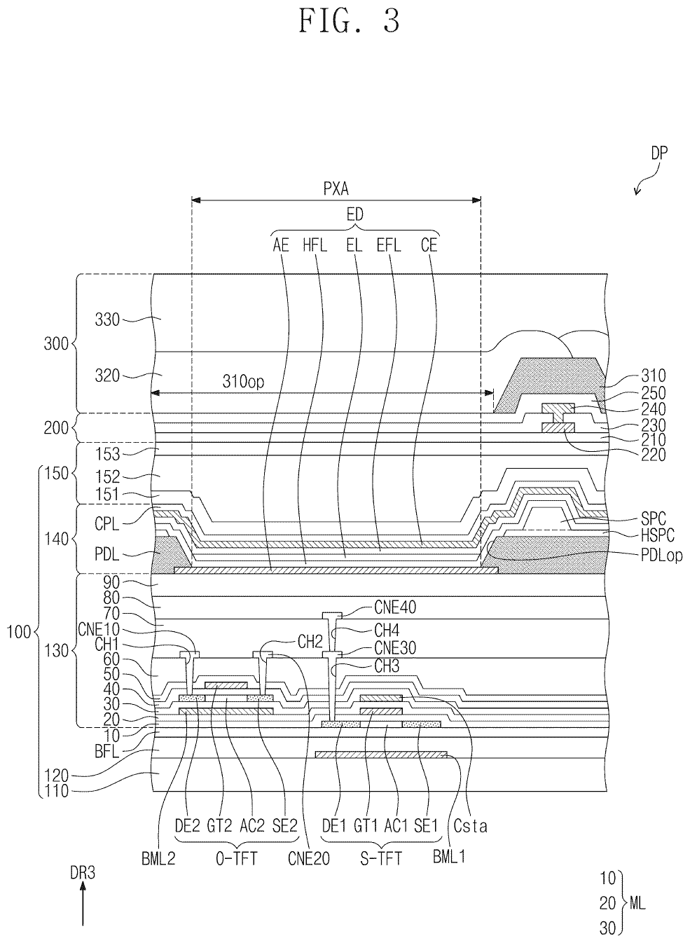

FIG. 3 is a cross-sectional view of a display panel DP according to one or more embodiments of the present disclosure.

Referring to FIG. 3, the display panel DP may include a display layer 100, a sensor layer 200, and a reflection-preventing (e.g., reflection-reducing layer) 300. The display layer 100 may include a base layer 110, a barrier layer 120, a circuit layer 130, an element layer 140, and an encapsulation layer 150.

The base layer 110 may include at least one of a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. Meanwhile, in the present specification, the “˜˜”-based resin means one that includes a “˜˜” functional group.

Furthermore, the base layer 110 may include an inorganic material. For example, it may include at least one of silicon oxide, silicon nitride, silicon oxynitride, or amorphous silicon.

The barrier layer 120 may be located on the base layer 110 (as used herein, “located on” may mean “above”). The barrier layer 120 may include an inorganic material. For example, it may include at least one of silicon oxide, silicon nitride, silicon oxynitride, or amorphous silicon. The barrier layer 120 may include a first lower light-shielding layer BML1.

The first lower light-shielding layer BML1 may be referred to as a first lower layer, a first metal layer, a first lower electrode layer, a first lower shield layer, a first light-shielding layer, a first electrode layer, a first shield layer, or a first overlapping layer.

A buffer layer BFL may be located on the barrier layer 120. The buffer layer BFL may reduce or prevent metal atoms or impurities diffusing from the base layer 110 to the semiconductor layer. Furthermore, the buffer layer BFL may control a heat supply rate during a crystallization process for forming the semiconductor layer to uniformly form the semiconductor layer.

The buffer layer BFL may include a plurality of inorganic layers. For example, the buffer layer BFL may include silicon nitride, silicon oxide.

The circuit layer 130 may be located on the buffer layer BFL, and the element layer 140 may be located on the circuit layer 130.

Referring to FIG. 3, each of the plurality of pixels PX (see FIG. 1) may include a silicon semiconductor transistor S-TFT and an oxide semiconductor transistor O-TFT. The silicon semiconductor transistor S-TFT may be one of the first, second, fifth, sixth, seventh, or eighth transistors T1, T2, T5, T6, T7, and T8 described in FIG. 2, and the oxide semiconductor transistor O-TFT may be one of the third or fourth transistors T3 and T4.

First semiconductor patterns DE1, AC1, and SE1 may be located on the buffer layer BFL. The first semiconductor patterns DE1, AC1, and SE1 may include a silicon semiconductor. For example, the silicon semiconductor may include amorphous silicon, polycrystalline silicon, and the like. For example, the first semiconductor patterns DE1, AC1, and SE1 may include a low-temperature poly silicon semiconductor.

FIG. 3 only illustrates a portion of the first semiconductor pattern DE1, AC1, and SE1 located on a buffer layer BFL, and the first semiconductor pattern DE1, AC1, and SE1 may be further located in other areas. The first semiconductor pattern DE1, AC1, and SE1 may be arranged in a corresponding rule or pattern across pixels. The first semiconductor pattern DE1, AC1, and SE1 may have different electrical properties depending on whether they are doped. The first semiconductor pattern DE1, AC1, and SE1 may include a source or drain area DE1 and SE1 having a high conductivity and an active area AC1 having a low conductivity. The source or drain area DE1 or SE1 may be doped with an N-type dopant or a P-type dopant. A P-type transistor may include a doping area that is doped with a P-type dopant, and an N-type transistor may include a doping area that is doped with an N-type dopant. The active area AC1 may be a non-doping area or an area that is doped at a lower concentration than that of the source or drain area DE1 or SE1.

A conductivity of the source or drain area DE1 or SE1 is greater than that of the active area AC1, and the source or drain area DE1 or SE1 may substantially function as an electrode or a signal line. The active area AC1 may substantially correspond to a channel of the transistor.

The source area SE1, the active area AC1, and the drain area DE1 of the silicon semiconductor transistor S-TFT may be formed from the first semiconductor patterns DE1, AC1, and SE1. The source area SE1 and the drain area DE1 may respectively extend in opposite directions from the active area AC1 on a cross-section.

The circuit layer 130 may include a plurality of inorganic layers and a plurality of organic layers. In one or more embodiments, the first to fifth insulation layers 10, 20, 30, 40, and 50 that are sequentially laminated on the buffer layer BFL may be inorganic layers, and the sixth to ninth insulation layers 60, 70, 80, and 90 may be organic layers.

The first insulation layer 10 may be located on the buffer layer BFL. The first insulation layer 10 may cover the first semiconductor pattern DE1, AC1, and SE1. The first insulation layer 10 may be an inorganic layer and/or an organic layer, and may have a single-layer or multi-layer structure. The first insulation layer 10 may include at least one of aluminum oxide, titanium oxide, silicon oxide, silicon nitride, silicon oxynitride, zirconium oxide, or hafnium oxide. The first insulation layer 10 may be a single-layer silicon oxide layer. An insulation layer of the circuit layer 130, which will be described below, as well as the first insulation layer 10 may have a single-layer or multi-layer structure.

A gate electrode GT1 of the silicon semiconductor transistor S-TFT may be located on the first insulation layer 10. The gate electrode GT1 may be a portion of a metal pattern. The gate electrode GT1 may overlap the active area AC1. In the process of doping the first semiconductor pattern DE1, AC1, and SE1, the gate electrode GT1 may function as a mask. The gate electrode GT1 may include titanium, silver, an alloy that contains silver, molybdenum, an alloy that contains molybdenum, aluminum, an alloy that contains aluminum, aluminum nitride, tungsten, tungsten nitride, copper, indium tin oxide, or indium zinc oxide, but is not particularly limited.

The second insulation layer 20 may be located on the first insulation layer 10, and may cover the gate electrode GT1. The second insulation layer 20 may be an inorganic layer, and may have a single-layer or multi-layer structure. The second insulation layer 20 may include at least one of silicon oxide, silicon nitride, or silicon oxynitride. The second insulation layer 20 may have a single-layer structure including a silicon nitride layer. A second lower light-shielding layer BML2 may be located on the second insulation layer 20. The second lower light-shielding layer BML2 may be the same material as that of the first lower light-shielding layer BML1.

A third insulation layer 30 may be located on the second insulation layer 20. The third insulation layer 30 may be an inorganic layer and may have a single-layer or multi-layer structure. For example, the third insulation layer 30 may have a multi-layer structure including a silicon oxide layer and a silicon nitride layer. One electrode Csta of the capacitor Cst (see FIG. 2) may be located between the second insulation layer 20 and the third insulation layer 30. Furthermore, another electrode of the capacitor Cst (see FIG. 2) may be located between the first insulation layer 10 and the second insulation layer 20.

The intermediate insulation layer ML may include the first insulation layer 10, the second insulation layer 20, and the third insulation layer 30. A second semiconductor pattern DE2, AC2, and SE2 may be located on the intermediate insulation layer ML. The second semiconductor pattern DE2, AC2, and SE2 may include an oxide semiconductor. The oxide semiconductor may include a plurality of areas that are distinguished depending on whether a metal oxide is reduced. The reduced areas DE2 and SE2, in which the metal oxide is reduced, have a greater conductivity than that of the non-reduced area AC2, in which the metal oxide is not reduced. The reduced area DE2 and SE2 is substantially a source or drain area DE2 or SE2 of the transistor, and the non-reduced area AC2 corresponds to an active area AC2 of the transistor. In other words, a portion of the second semiconductor pattern DE2, AC2, and SE2 may be the active area AC2 of the transistor, another portion may be the source or drain area DE2 or SE2 of the transistor, and another part may be a signal transmission area. The active area AC2 may substantially correspond to a channel of the transistor.

The source area SE2, the active area AC2, and the drain area DE2 of the oxide semiconductor transistor O-TFT may be formed from a second semiconductor pattern DE2, AC2, and SE2. The source area SE2 and the drain area DE2 may extend in opposite directions from the active area AC2 on a cross-section.

The fourth insulation layer 40 may be located on the third insulation layer 30. The fourth insulation layer 40 may cover the second semiconductor pattern DE2, AC2, and SE2. The fourth insulation layer 40 may be an inorganic layer, and may have a single-layer or multi-layer structure. The fourth insulation layer 40 may include at least one of aluminum oxide, titanium oxide, silicon oxide, silicon nitride, silicon oxynitride, zirconium oxide, or hafnium oxide. The fourth insulation layer 40 may have a single-layer structure including silicon oxide.

A gate electrode GT2 of the oxide semiconductor transistor O-TFT is located on the fourth insulation layer 40. The gate electrode GT2 may be a portion of a metal pattern. The gate electrode GT2 overlaps the active area AC2. In a process of reducing the second semiconductor pattern DE2, AC2, and SE2, the gate electrode GT2 may function as a mask.

The fifth insulation layer 50 may be located on the fourth insulation layer 40, and may cover the gate electrode GT2. The fifth insulation layer 50 may be an inorganic layer and/or an organic layer, and may have a single-layer or multi-layer structure. For example, the fifth insulation layer 50 may have a multi-layer structure including a silicon oxide layer and a silicon nitride layer.

The sixth insulation layer 60 may be located on the fifth insulation layer 50. The first connection electrode CNE10 may be located on the sixth insulation layer 60. The first connection electrode CNE10 may be connected to the drain area DE2 of the oxide semiconductor transistor O-TFT through a first contact hole CH1 that passes through the fourth to sixth insulation layers 40, 50, and 60.

The second connection electrode CNE20 may be located on the sixth insulation layer 60. The second connection electrode CNE20 may be connected to the source area SE2 of the oxide semiconductor transistor O-TFT through a second contact hole CH2 that passes through the fourth to sixth insulation layers 40, 50, and 60.

The third connection electrode CNE30 may be located on the sixth insulation layer 60. The third connection electrode CNE30 may be connected to the drain area DE1 of the silicon semiconductor transistor S-TFT through a third contact hole CH3 that passes through the first to sixth insulation layers 10, 20, 30, 40, 50, and 60.

The seventh insulation layer 70 may be located on the sixth insulation layer 60, and may cover the first connection electrode CNE10, the second connection electrode CNE20, and the third connection electrode CNE30.

The fourth connection electrode CNE40 may be located on the seventh insulation layer 70. The fourth connection electrode CNE40 may be connected to the third connection electrode CNE30 through the fourth contact hole CH4 that passes through the seventh insulation layer 70.

The eighth insulation layer 80 may be located on the seventh insulation layer 70, and may cover the fourth connection electrode CNE40. The ninth insulation layer 90 may be located on the eighth insulation layer 80.

Each of the sixth insulation layer 60, the seventh insulation layer 70, the eighth insulation layer 80, and the ninth insulation layer 90 may be an organic layer. For example, each of the sixth insulation layer 60, the seventh insulation layer 70, the eighth insulation layer 80, and the ninth insulation layer 90 may include a general-purpose polymer, such as benzocyclobutene (BCB), polyimide, hexamethyldisiloxane (HMDSO), polymethylmethacrylate (PMMA), or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and a blend thereof.

An element layer 140 including a light-emitting element ED may be located on the circuit layer 130. The light-emitting element ED may include a pixel electrode AE (or an anode), a first functional layer HFL, a light emission layer EL, a second functional layer EFL, and a common electrode CE (or a cathode). The first functional layer HFL, the second functional layer EFL, and the common electrode CE may be provided in common in the pixels PX (see FIG. 1).

The pixel electrode AE may be located on the ninth insulation layer 90. The pixel electrode AE may be a (semi) light-transmitting electrode or a reflection electrode. In one or more embodiments, the pixel electrode AE may have a reflective layer that is formed of silver, magnesium, aluminum, platinum, palladium, gold, nickel, neodymium, iridium, chromium, or a compound thereof, and a transparent or translucent electrode layer that is formed on the reflective layer. The transparent or translucent electrode layer may include at least one selected from the group comprising indium tin oxide, indium zinc oxide, indium gallium zinc oxide, zinc oxide, indium oxide, or aluminum-doped zinc oxide. For example, the pixel electrode AE may include a multi-layer structure, in which indium tin oxide, silver, and indium tin oxide are sequentially laminated.

A pixel definition film PDL may be located on the ninth insulation layer 90. The pixel definition film PDL may have a property of absorbing light, and for example, the pixel definition film PDL may have a black color. The pixel definition film PDL may include a black coloring agent. The black coloring agent may include a black dye or a black pigment. The black coloring agent may include carbon black, a metal such as chromium, or an oxide thereof.

An opening PDLop that exposes a portion of the pixel electrode AE may be defined in the pixel definition film PDL. That is, the pixel definition film PDL may cover a periphery of the corresponding pixel electrode AE. Light emission electrodes may be defined by the opening PDLop defined in the pixel definition film PDL. For example, a light emission electrode PXA may be defined in the light-emitting element ED.

A spacer HSPC may be located on the pixel definition film PDL. A protruding spacer SPC may be located on the spacer HSPC. The spacer HSPC and the protruding spacer SPC may have an integral shape, and may be formed of the same material. For example, the spacer HSPC and the protruding spacer SPC may be formed through the same process by a halftone mask. However, this is an example and the present disclosure is not limited thereto. For example, the spacer HSPC and the protruding spacer SPC may include different materials, and may be formed by separate processes.

A height (or thickness) of the protruding spacer SPC may be greater than a height (or thickness) of the spacer HSPC. The height of the spacer HSPC may be about 0.1 μm to about 0.5 μm, and the entire height of the spacer HSPC and the protruding spacer SPC may be about 1.1 μm to about 2.0 μm. However, the height of the spacer HSPC and the entire height of the spacer HSPC and the protruding spacer SPC are not limited to the examples described above.

The first functional layer HFL may be located on the pixel electrode AE, the pixel definition film PDL, the spacer HSPC, and the protruding spacer SPC. The first functional layer HFL may include a hole transport layer HTL, a hole injection layer HIL, or both a hole transport layer and a hole injection layer. The first functional layer HFL may be located over the entire display area DA (see FIG. 1).

The light emission layer EL is located on the first functional layer HFL, and may be located in an area corresponding to an opening PDLop of the pixel definition film PDL. The light emission layer EL may include an organic material, an inorganic material, or an organic-inorganic material that emits light of a corresponding color.

A second functional layer EFL is located over the first functional layer HFL, and may cover the light emission layer EL. The second functional layer EFL may include an electron transport layer ETL, an electron injection layer EIL, or both of an electron transport layer and an electron injection layer. The second functional layer EFL may be located over the entire display area DA (see FIG. 1).

The common electrode CE may be located on the second functional layer EFL. The common electrode CE may be located in the display area DA (see FIG. 1).

The element layer 140 may further include a capping layer CPL that is located on the common electrode CE. The capping layer CPL may serve to improve a light emission efficiency by the principle of constructive interference. For example, the capping layer CPL may include a material having a refractive index of about 1.6 or more for light having a wavelength of about 589 nm. The capping layer CPL may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, CI, Br, I, or any combination thereof.

The encapsulation layer 150 may be located on the element layer 140. The encapsulation layer 150 may include an inorganic layer 151, an organic layer 152, and an inorganic layer 153 that are sequentially laminated, but the layers that constitutes the encapsulation layer 150 are not limited thereto.

The inorganic layers 151 and 153 may protect the element layer 140 from moisture and oxygen, and the organic layer 152 may protect the element layer 140 from foreign substances, such as dust particles. The inorganic layers 151 and 153 may include a silicon nitride layer, a silicon oxynitride layer, a silicon oxide layer, a titanium oxide layer, or an aluminum oxide layer. The organic layer 152 may include an acrylic-based organic layer, but is not limited thereto.

The sensor layer 200 may be located on the display layer 100. The sensor layer 200 may be referred to as a sensor, an input sensing layer, or an input sensing panel. The sensor layer 200 may include a sensor base layer 210, a first sensor conductive layer 220, a sensor insulation layer 230, a second sensor conductive layer 240, and a sensor cover layer 250.

The sensor base layer 210 may be directly located on the display layer 100. The sensor base layer 210 may be an inorganic layer including at least one of silicon nitride, silicon oxynitride, or silicon oxide. Alternatively, the sensor base layer 210 may be an organic layer including an epoxy resin, an acrylic resin, or an imide-based resin. The sensor base layer 210 may have a single-layer structure or a multi-layer structure, in which it is laminated along a third direction DR3.

Each of the first sensor conductive layer 220 and the second sensor conductive layer 240 may have a single-layer structure or a multi-layer structure, in which it is laminated along the third direction DR3.

The conductive layer of the single-layer structure may include a metal layer or a transparent conductive layer. The metal layer may include molybdenum, silver, titanium, copper, aluminum, or an alloy thereof. The transparent conductive layer may include a transparent conductive oxide, such as indium tin oxide, indium zinc oxide, zinc oxide, or indium zinc tin oxide. Furthermore, the transparent conductive layer may include a conductive polymer such as PEDOT, metal nanowires, graphene, and the like.

The multi-layer conductive layer may include metal layers. The metal layers may have a three-layer structure of, for example, titanium/aluminum/titanium. The multi-layer conductive layer may include at least one metal layer and/or at least one transparent conductive layer.

The sensor insulation layer 230 may be located between the first sensor conductive layer 220 and the second sensor conductive layer 240. The sensor insulation layer 230 may include an inorganic film. The inorganic film may include at least one of aluminum oxide, titanium oxide, silicon oxide, silicon nitride, silicon oxynitride, zirconium oxide, or hafnium oxide.

The sensor insulation layer 230 may include an organic film. The organic film may include at least any one of an acrylic resin, a methacrylic resin, a polyisoprene, a vinyl resin, an epoxy resin, a urethane resin, a cellulose resin, a siloxane resin, a polyimide resin, a polyamide resin, or a perylene resin.

The sensor cover layer 250 is located on the sensor insulation layer 230, and may cover the second sensor conductive layer 240. The second sensor conductive layer 240 may include a conductive pattern. The sensor cover layer 250 may cover the conductive pattern, and may reduce or eliminate a probability of a damage occurring to the conductive pattern in a subsequent process. The sensor cover layer 250 may include an inorganic material. For example, the sensor cover layer 250 may include silicon nitride, but is not particularly limited thereto. In one or more embodiments of the present disclosure, the sensor cover layer 250 may be omitted.

The reflection-preventing layer 300 may be located on the sensor layer 200. The reflection-preventing layer 300 may include a division layer 310, a color filter 320, and a planarization layer 330.

The division layer 310 may overlap the conductive pattern of the second sensor conductive layer 240. The sensor cover layer 250 may be located between the division layer 310 and the second sensor conductive layer 240. The division layer 310 may reduce or prevent external light reflected by the second sensor conductive layer 240. A material that constitutes the division layer 310 is not particularly limited as long as it is a material that absorbs light. The division layer 310 may be a layer having a black color, and in one or more embodiments, the division layer 310 may include a black component (a black coloring agent). The black coloring agent may include a black dye or a black pigment. The black coloring agent may include carbon black, a metal such as chromium, or an oxide thereof.

A division opening 310op may be defined in the division layer 310. The division opening 310op may overlap the light emission layer EL. The color filter 320 may correspond to the division opening 310op. The color filter 320 may transmit light provided from the light emission layer EL that overlaps the color filter 320.

The planarization layer 330 may cover the division layer 310 and the color filter 320. The planarization layer 330 may include an organic material, and may provide a flat surface on an upper surface of the planarization layer 330. In one or more embodiments, the planarization layer 330 may be omitted.

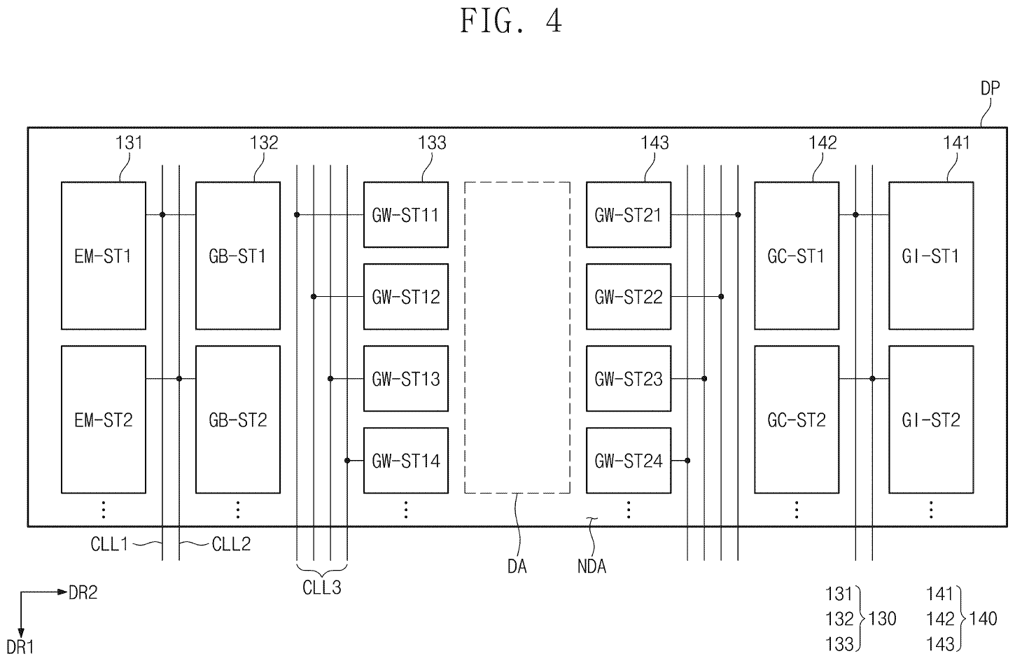

FIG. 4 is a block diagram of a display panel DP according to one or more embodiments of the present disclosure.

Referring to FIG. 4, the display panel DP may include a first driver 13, a

second driver 14, a first clock line CLL1, a second clock line CLL2, and a plurality of third clock lines CLL3.

The first driver 13 may include a first driving circuit 131, a second driving circuit 132, and a (3-1)-th driving circuit 133. The second driver 14 may include a fourth driving circuit 141, a fifth driving circuit 142, and a (3-2)-th driving circuit 143.

In one or more embodiments of the present disclosure, the first driving circuit 131 may refer to a light emission driving circuit 131, and the second driving circuit 132 may refer to a black-scan-driving circuit 132. Referring to FIGS. 1 and 2 together, the light emission driving circuit 131 may be electrically connected to the light emission control lines EML1 to EMLn, and may output light emission signals to the light emission control lines EML1 to EMLn. The black-scan-driving circuit 132 may be electrically connected to the black scan lines GBL1 to GBLn, and may output black scan signals to the black scan lines GBL1 to GBLn.

The first driving circuit 131 may include a plurality of first stages EM-ST1 and EM-ST2. The second driving circuit 132 may include a plurality of second stages GB-ST1 and GB-ST2. FIG. 4 illustrates, by way of example, two first stages EM-ST1 and EM-ST2 and two second stages GB-ST1 and GB-ST2. For example, the first stages EM-ST1 and EM-ST2 may include a (1-1)-th stage EM-ST1 and a (1-2)-th stage EM-ST2, and the second stages GB-ST1 and GB-ST2 may include a (2-1)-th stage GB-ST1 and a (2-2)-th stage GB-ST2. The numbers of the first stages EM-ST1 and EM-ST2 and the second stages GB-ST1 and GB-ST2 included in the entire display panel DP may be “N”, respectively. However, the present disclosure is not limited thereto, and the numbers of the stages may be different.

The first stages EM-ST1 and EM-ST2 may be arranged along the first direction DR1, and the second stages GB-ST1 and GB-ST2 may be arranged along the first direction DR1. The display panel DP may include at least one clock line CLL1 or CLL2 that is located between the first stages EM-ST1 and EM-ST2 and the second stages GB-ST1 and GB-ST2 and extends along the first direction DR1.

In one or more embodiments of the present disclosure, a first clock line CLL1 that extends along the first direction DR1, and a second clock line CLL2 that is spaced therefrom in the second direction DR2 that crosses the first direction DR1, may be located between the first stages EM-ST1 and EM-ST2 and the second stages GB-ST1 and GB-ST2. However, the present disclosure is not limited thereto, and the numbers of clock lines CLL1 and CLL2 may be 1, 2, or more.

In one or more embodiments of the present disclosure, the (1-1)-th stage EM-ST1 and the (2-1)-th stage GB-ST1 may share a first clock line CLL1. A first clock signal that is received through the first clock line CLL1 may be commonly transmitted to the (1-1)-th stage EM-ST1 and the (2-1)-th stage GB-ST1. The (1-2)-th stage EM-ST2 and the (2-2)-th stage GB-ST2 may share a second clock line CLL2. A second clock signal that is received through the second clock line CLL2 may be commonly transmitted to the (1-2)-th stage EM-ST2 and the (2-2)-th stage GB-ST2.

In FIG. 4, the (1-1)-th stage EM-ST1 and the (2-1)-th stage GB-ST1 share one first clock line CLL1, and the (1-2)-th stage EM-ST2 and the (2-2)-th stage GB-ST2 share one second clock line CLL2, but the present disclosure is not limited thereto. For example, the (1-1)-th stage EM-ST1 and the (2-1)-th stage GB-ST1 may share both the first clock line CLL1 and the second clock line CLL2, and the (1-2)-th stage EM-ST2 and the (2-2)-th stage GB-ST2 may also share both the first clock line CLL1 and the second clock line CLL2.

The first driving circuit 131 including the first stages EM-ST1 and EM-ST2 and the second driving circuit 132 including the second stages GB-ST1 and GB-ST2 may share at least one clock line CLL1 or CLL2 whereby the numbers of the clock lines CLL1 and CLL2 may be reduced. Then, power consumptions of the first driving circuit 131 and the second driving circuit 132 may be reduced by reducing the numbers of the clock lines CLL1 and CLL2.

Referring to FIG. 4, the (3-1)-th driving circuit 133 may refer to a first write-scan-driving circuit 133, and the (3-2)-th driving circuit 143 may refer to a second write-scan-driving circuit 143. Referring to FIG. 1 and FIG. 2 together, the first write-scan-driving circuit 133 and the second write-scan-driving circuit 143 may refer to write-scan-driving circuits 133 and 143. The write-scan-driving circuits 133 and 143 may be electrically connected to the write scan lines GWL1 to GWLn, and may output write scan signals to the write scan lines GWL1 to GWLn.

The (3-1)-th driving circuit 133 may include a plurality of (3-1)-th stages GW-

ST11, GW-ST12, GW-ST13, and GW-ST14. The (3-2)-th driving circuit 143 may include a plurality of (3-2)-th stages GW-ST21, GW-ST22, GW-ST23, and GW-ST24. FIG. 4 illustrates, by way of example, four (3-1)-th stages GW-ST11, GW-ST12, GW-ST13, and GW-ST14 and four (3-2)-th stages GW-ST21, GW-ST22, GW-ST23, and GW-ST24.

The (3-1)-th stages GW-ST11, GW-ST12, GW-ST13, and GW-ST14 may be arranged along the first direction DR1, and the (3-2)-th stages GW-ST21, GW-ST22, GW-ST23, and GW-ST24 may be arranged along the first direction DR1. The (3-1)-th stages GW-ST11, GW-ST12, GW-ST13, and GW-ST14 and the (3-2)-th stages GW-ST21, GW-ST22, GW-ST23, and GW-ST24 may be spaced apart in the second direction DR2 with the display area DA being interposed therebetween. However, the present disclosure is not limited thereto, and the (3-1)-th stages GW-ST11, GW-ST12, GW-ST13, and GW-ST14 and the (3-2)-th stages GW-ST21, GW-ST22, GW-ST23, and GW-ST24 may overlap the display area DA.

The (3-1)-th stages GW-ST11, GW-ST12, GW-ST13, and GW-ST14 may be electrically connected to a plurality of third clock lines CLL3. FIG. 4 illustrates, by way of example, four third clock lines CLL3, and may have a different number, in one or more embodiments.

Referring to FIG. 4, the third clock signals received through the four third clock lines CLL3 may be transmitted to the (3-1)-th stages GW-ST11, GW-ST12, GW-ST13, and GW-ST14.

The (3-2)-th stages GW-ST21, GW-ST22, GW-ST23, and GW-ST24 may have substantially the same configuration as that of the (3-1)-th stages GW-ST11, GW-ST12, GW-ST13, and GW-ST14. The (3-2)-th stages GW-ST21, GW-ST22, GW-ST23, and GW-ST24 may also be electrically connected to a plurality of clock lines, and clock signals received through the plurality of clock lines may be transmitted to the (3-2)-th stages GW-ST21, GW-ST22, GW-ST23, and GW-ST24. However, the present disclosure is not limited thereto, and may be different.

In one or more embodiments of the present disclosure, the numbers of the (3-1)-th stages GW-ST11, GW-ST12, GW-ST13, and GW-ST14 and the (3-2)-th stages GW-ST21, GW-ST22, GW-ST23, and GW-ST24 may be greater than the number of the first stages EM-ST1 and EM-ST2 and the second stages GB-ST1 and GB-ST2. However, the present disclosure is not limited thereto.

The fourth driving circuit 141 may refer to an initialization-scan-driving circuit 141, and the fifth driving circuit 142 may refer to a compensation-scan-driving circuit 142. Referring to FIG. 1 and FIG. 2 together, the initialization-scan-driving circuit 141 may be electrically connected to the initialization scan lines GIL1 to GILn, and may output initialization scan signals to the initialization scan lines GIL1 to GILn. The compensation-scan-driving circuit 142 may be electrically connected to the compensation scan lines GCL1 to GCLn, and may output compensation scan signals to the compensation scan lines GCL1 to GCLn.

The fourth driving circuit 141 may include a plurality of fourth stages GI-ST1 and GI-ST2. The fifth driving circuit 142 may include a plurality of fifth stages GC-ST1 and GC-ST2. FIG. 4 illustrates, by way of example, two fourth stages GI-ST1 and GI-ST2 and two fifth stages GC-ST1 and GC-ST2.

The configurations of the fourth stages GI-ST1 and GI-ST2 and the fifth stages GC-ST1 and GC-ST2 may have similar configurations to those of the first stages EM-ST1 and EM-ST2 and the second stages GB-ST1 and GB-ST2. The fourth stages GI-ST1 and GI-ST2 and the fifth stages GC-ST1 and GC-ST2 may also share at least one clock line CLL1 or CLL2, like the first stages EM-ST1 and EM-ST2 and the second stages GB-ST1 and GB-ST2. Accordingly, the power consumptions of the fourth driving circuit 141 and the fifth driving circuit 142 may be reduced by reducing the number of clock lines CLL1 and CLL2.

In one or more embodiments of the present disclosure, the first driving circuit 131, the second driving circuit 132, and the (3-1)-th driving circuit 133 may be arranged on a first side of the display panel DP, and the fourth driving circuit 141, the fifth driving circuit 142, and the (3-2)-th driving circuit 143 may be arranged on a second side of the display panel DP. Then, the first driving circuit 131, the second driving circuit 132, the (3-1)-th driving circuit 133, the fourth driving circuit 141, the fifth driving circuit 142, and the (3-2)-th driving circuit 143 may be spaced apart from each other with the display area DA being interposed therebetween. The driving circuits may be located in the non-display area NDA of the display panel DP. However, the present disclosure is not limited thereto, and the driving circuits may be located in the display area DA.

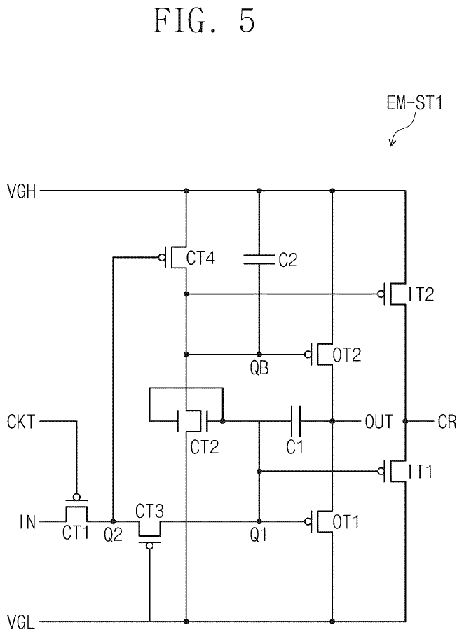

FIG. 5 is a circuit diagram of a (1-1)-th stage EM-ST1 according to one or more embodiments of the present disclosure.

Referring to FIG. 5, the (1-1)-th stage EM-ST1 may include first and second output transistors OT1 and OT2, first to fourth control transistors CT1, CT2, CT3, and CT4, first and second capacitors C1 and C2, and first and second carry transistors IT1 and IT2. FIG. 5 illustrates the (1-1)-th stage EM-ST1 as an example, but the configurations of other stages may be the same. Furthermore, an equivalent circuit diagram illustrated in FIG. 5 is only an example, and the equivalent circuit diagram that constitutes the (1-1)-th stage EM-ST1 may be modified in various ways.

The first and second output transistors OT1 and OT2 are connected to an output terminal OUT. The first output transistor OT1 is connected between the output terminal OUT and a first voltage terminal VGL, and is operated in response to a potential of a first node Q1. The first output transistor OT1 includes a first electrode that is connected to the output terminal OUT, a second electrode that is connected to the first voltage terminal VGL, and a third electrode that is connected to the first node Q1.

The second output transistor OT2 is connected between the output terminal OUT and the second voltage terminal VGH, and is operated in response to a potential of a second node QB. The second output transistor OT2 includes a first electrode that is connected to the second voltage terminal VGH, a second electrode that is connected to the output terminal OUT, and a third electrode that is connected to the second node QB.

As an example of the present disclosure, each of the first and second output transistors OT1 and OT2 may be a P-type transistor having a low-temperature poly silicon semiconductor as a semiconductor layer.

A first control transistor CT1 is connected between an input terminal IN, which receives a previous carry signal from a previous stage, and the third node Q2, and is operated in response to a clock signal provided through a clock terminal CKT. The first control transistor CT1 includes a first electrode that is connected to the third node Q2, a second electrode that is connected to the input terminal IN, and a third electrode that is connected to the clock terminal CKT.

A second control transistor CT2 is connected between the second node QB and the first voltage terminal VGL, and is operated in response to the potential of the first node Q1. The second control transistor CT2 includes a first electrode that is connected to the second node QB, a second electrode that is connected to the first voltage terminal VGL, and a third electrode that is connected to the first node Q1. The second control transistor CT2 may further include a back gate. The back gate of the second control transistor CT2 may be connected to the first node Q1. The back gate of the second control transistor CT2 may be omitted.

A third control transistor CT3 is connected between the third node Q2 and the first node Q1, and is operated in response to a low voltage provided through the first voltage terminal VGL. The third control transistor CT3 includes a first electrode that is connected to the third node Q2, a second electrode that is connected to the first node Q1, and a third electrode that is connected to the first voltage terminal VGL.

A fourth control transistor CT4 is connected between the second node QB and the second voltage terminal VGH, and is operated in response to the potential of the third node Q2. The fourth control transistor CT4 includes a first electrode that is connected to the second voltage terminal VGH, a second electrode that is connected to the second node QB, and a third electrode that is connected to the third node Q2.

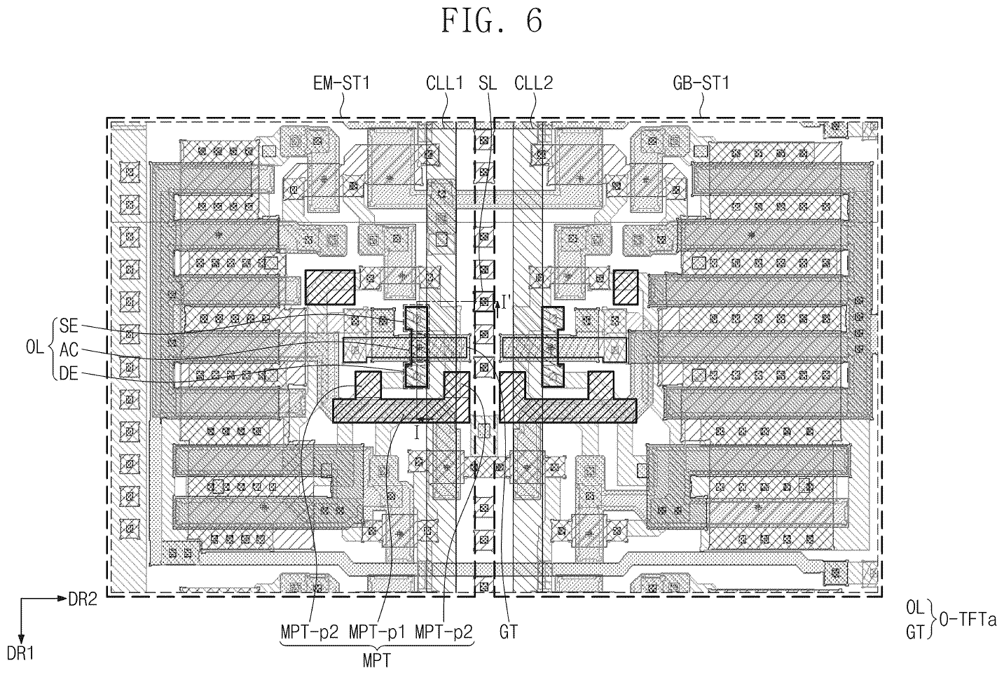

As an example of the present disclosure, each of the first, third, and fourth control transistors CT1, CT3, and CT4 may be a P-type transistor having a low-temperature poly silicon semiconductor as a semiconductor layer. The second control transistor CT2 may be an N-type transistor having an oxide semiconductor as a semiconductor layer. The second control transistor CT2 may include an oxide semiconductor layer OL and a gate electrode GT of FIG. 6, which will be described below.

The (1-1)-th stage EM-ST1 further includes a first capacitor C1 that is connected between the output terminal OUT and the first node Q1, and a second capacitor C2 that is connected between the second node QB and the second voltage terminal VGH. A potential difference between the first and third electrodes of the first output transistor OT1 may be maintained at a threshold voltage or more by the first capacitor C1.

The first and second carry transistors IT1 and IT2 are connected to a carry terminal CR. A first carry transistor IT1 is connected between the carry terminal CR and the first voltage terminal VGL, and operates depending on the potential of the first node Q1. The first carry transistor IT1 includes a first electrode that is connected to the carry terminal CR, a second electrode that is connected to the first voltage terminal VGL, and a third electrode that is connected to the first node Q1.

A carry transistor IT2 is connected between the carry terminal CR and the second voltage terminal VGH, and is operated according to a potential of the second node QB. The second carry transistor IT2 includes a first electrode that is connected to the second voltage terminal VGH, a second electrode that is connected to the carry terminal CR, and a third electrode that is connected to the second node QB.

As an example of the present disclosure, the first carry transistor IT1 and the second carry transistor IT2 may be P-type transistors having a low-temperature poly silicon semiconductor as a semiconductor layer.

In one or more embodiments of the present disclosure, it is illustrated that the third electrode of the third control transistor CT3, the second electrode of the first output transistor OT1, and the second electrode of the first carry transistor IT1 are connected to the first voltage terminal VGL, but the present disclosure is not limited thereto. For example, the (1-1)-th stage EM-ST1 may include a first voltage terminal VGL and a (1-1)-th voltage terminal of different levels, and the third electrode of the third control transistor CT3 and the second electrode of the first output transistor OT1 may be connected to the first voltage terminal VGL, and the second electrode of the first carry transistor IT1 may be connected to the (1-1)-th voltage terminal.

FIG. 6 is an enlarged plan view of a portion of a display panel DP according to one or more embodiments of the present disclosure.

Referring to FIG. 4 and FIG. 6, FIG. 6 illustrates, by way of example, a (1-1)-th stage EM-ST1, among a plurality of first stages EM-ST1 and EM-ST2 of the first driving circuit 131, and a (2-1)-th stage GB-ST1, among a plurality of second stages GB-ST1 and GB-ST2 of the second driving circuit 132. The plurality of fourth stages GI-ST1 and GI-ST2 and the plurality of fifth stages GC-ST1 and GC-ST2 may also include substantially similar layouts.

Referring to FIG. 6, the display panel DP may include a (1-1)-th stage EM-ST1, a (2-1)-th stage GB-ST1, a first clock line CLL1, a second clock line CLL2, and a dummy semiconductor pattern SL.

Each of the (1-1)-th stage EM-ST1 and the (2-1)-th stage GB-ST1 may include an oxide semiconductor transistor O-TFTa and a conductive pattern MPT. The oxide semiconductor transistor O-TFTa may have a lamination structure that is similar to that of the oxide semiconductor transistor O-TFT of FIG. 3.

The oxide semiconductor transistor O-TFTa may include an oxide semiconductor layer OL that extends in the first direction DR1, and a gate electrode GT that extends in the second direction DR2 and crosses the oxide semiconductor layer OL. The gate electrode GT may overlap at least a portion of the oxide semiconductor layer OL.

The oxide semiconductor layer OL may include a first area DE, an active area AC, and a second area SE. The second area SE may be spaced apart from the first area DE with the active area AC being interposed therebetween. For example, the first area DE may be a drain area, and the second area SE may be a source area, but the present disclosure is not particularly limited thereto.

Referring to FIG. 6, the first area DE of the oxide semiconductor layer OL may be an area protruding in the first direction DR1 with respect to the gate electrode GT. The second area SE2 of the oxide semiconductor layer OL may be an area protruding in an opposite direction to the first direction DR1 with respect to the gate electrode GT.

The conductive pattern MPT may be located adjacent to the oxide semiconductor layer OL. When viewed on a plane, the conductive pattern MPT may surround (e.g., partially surround) at least a portion of the first area DE of the oxide semiconductor layer OL. For example, the conductive pattern MPT may include a first portion MPT-p1 that faces the first area DE in the first direction DR1, and second portions MPT-p2 that protrudes from the first portion MPT-p1. The second portions MPT-p2 may be spaced apart from each other with the first area DE being interposed therebetween. In one or more other embodiments of the present disclosure, any one of the first portion MPT-p1 or the second portions MPT-p2 may be omitted. The conductive pattern MPT may have a shape that is modified in various forms as long as it is located adjacent to the oxide semiconductor layer OL. The conductive pattern MPT may have an electrically floated island form. Accordingly, the conductive pattern MPT may be formed in a dummy form.

In one or more embodiments of the present disclosure, a material of the conductive pattern MPT may include titanium (Ti). When the conductive pattern MPT including titanium is located adjacent to the oxide semiconductor layer OL, hydrogen of the oxide semiconductor layer OL may be adsorbed to the conductive pattern MPT.

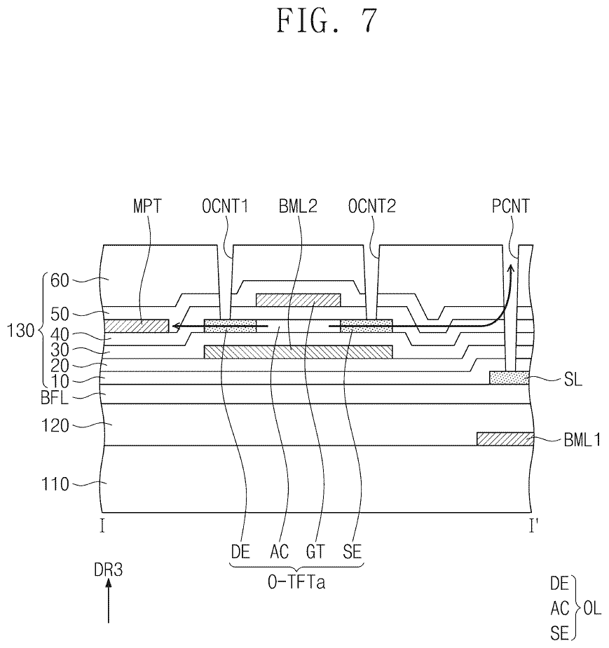

The (1-1)-th stage EM-ST1 and the (2-1)-th stage GB-ST1 may share at least one clock line CLL1 or CLL2. In this case, the dummy through-hole PCNT (see FIG. 7) for dehydrogenation may not be sufficiently located due to interference with surrounding wiring lines.

According to one or more embodiments of the present disclosure, the conductive pattern MPT may be located adjacent to the oxide semiconductor layer OL. Accordingly, hydrogen generated in the oxide semiconductor layer OL may be adsorbed by the conductive pattern MPT. As a result, the oxide semiconductor layer OL may be dehydrogenated sufficiently.

When the dehydrogenation is insufficient, a threshold voltage of the oxide semiconductor transistor O-TFTa may be negatively shifted, and in this case, even when a gate-source voltage of the oxide semiconductor transistor O-TFTa is about 0 V, the oxide semiconductor transistor O-TFTa may be turned on, causing a current leakage.

According to one or more embodiments of the present disclosure, hydrogen may be adsorbed by the conductive pattern MPT that is adjacent to the oxide semiconductor layer OL, and accordingly, the hydrogen concentration of the oxide semiconductor layer OL may be reduced. Accordingly, a degree, to which the threshold voltage of the oxide semiconductor transistor O-TFTa is negatively shifted, may be reduced or the threshold voltage may be positively shifted. As a result, a leakage due to the negative shift of the oxide semiconductor transistor O-TFTa may be reduced or eliminated. That is, a reliability of the first and second driving circuits 131 and 132 including the oxide semiconductor transistor O-TFTa and the oxide semiconductor transistor O-TFTa may be improved.

According to one or more embodiments of the present disclosure, a distance between the oxide semiconductor layer OL and the conductive pattern MPT may be tens of micrometers or less. For example, it may be about 10 micrometers or less, or it may be about 7.6 micrometers or less. The conductive pattern MPT may be generally located anywhere as long as it is adjacent to the oxide semiconductor layer OL.

The (1-1)-th stage EM-ST1 and the (2-1)-th stage GB-ST1 may share at least one of the first clock line CLL1 or the second clock line CLL2. Accordingly, the first clock line CLL1 and the second clock line CLL2 may be located between the (1-1)-th stage EM-ST1 and the (2-1)-th stage GB-ST1. However, the present disclosure is not limited thereto, and portions of the first clock line CLL1 and the second clock line CLL2 may overlap the (1-1)-th stage EM-ST1 and the (2-1)-th stage GB-ST1.

Referring to FIGS. 6 and 7, a dummy semiconductor pattern SL may be located between the (1-1)-th stage EM-ST1 and the (2-1)-th stage GB-ST1 and between the first clock line CLL1 and the second clock line CLL2.

A dummy through-hole PCNT that exposes at least a portion of the dummy semiconductor pattern SL may be defined in the dummy semiconductor pattern SL.

A plurality of dummy semiconductor patterns SL and a plurality of dummy through-holes PCNT may be provided, and the plurality of dummy semiconductor patterns SL may be arranged to be spaced apart from each other along the first direction DR1, and the plurality of dummy through-holes PCNT may also be arranged to be spaced apart from each other along the first direction DR1.

FIG. 7 is a cross-sectional view of a display panel DP taken along the line I-l′ of FIG. 6 according to one or more embodiments of the present disclosure.

FIG. 3 illustrates a cross-sectional view of a pixel circuit PXC in a display panel DP, and FIG. 7 illustrates a cross-sectional view taken along the line I-l′ of the (1-1)-th stage EM-ST1 of FIG. 6. Hereinafter, the same configurations as those of FIG. 3 is denoted by the same reference numerals, and a repeated description thereof will be omitted.

Referring to FIG. 7, the display panel DP may include a dummy semiconductor pattern SL and an oxide semiconductor transistor O-TFTa.

The dummy semiconductor pattern SL may be located on a buffer layer BFL. The dummy semiconductor pattern SL is located at a different layer from the oxide semiconductor layer OL, and may include a silicon semiconductor. For example, the silicon semiconductor may include amorphous silicon, polycrystalline silicon, and the like. For example, the dummy semiconductor pattern SL may include a low-temperature poly silicon semiconductor.

FIG. 7 only illustrates a portion of the dummy semiconductor pattern SL located on a buffer layer BFL, and dummy semiconductor patterns SL may be further located in other areas. Referring to FIG. 6 together, a plurality of dummy semiconductor patterns SL may be arranged to be spaced apart from each other along the first direction DR1.

The intermediate insulation layer ML may include the first insulation layer 10, the second insulation layer 20, and the third insulation layer 30. The intermediate insulation layer ML may be located on the buffer layer BFL, and may cover the dummy semiconductor pattern SL.

The oxide semiconductor layer OL may be located on the intermediate insulation layer ML. The fourth insulation layer 40 may be located on the intermediate insulation layer ML, and may cover the oxide semiconductor layer OL. The oxide semiconductor layer OL may be located at the same layer as the second semiconductor pattern DE2, AC2, and SE2 of FIG. 3. That is, the oxide semiconductor layer OL and the second semiconductor pattern DE2, AC2, and SE2 may be formed concurrently or substantially simultaneously by the same process, and may include the same material.

The gate electrode GT may be located on the fourth insulation layer 40. The gate electrode GT may overlap at least a portion of the oxide semiconductor layer OL. The gate electrode GT of the oxide semiconductor transistor O-TFTa illustrated in FIG. 7 may be located on the same layer as the gate electrode GT2 of the oxide semiconductor transistor O-TFT illustrated in FIG. 3. That is, the gate electrode GT of the oxide semiconductor transistor O-TFTa illustrated in FIG. 7 may be formed concurrently or substantially simultaneously through the same process as that of the gate electrode GT2 of the oxide semiconductor transistor O-TFT illustrated in FIG. 3.

The conductive pattern MPT may be located on the fourth insulation layer 40. The conductive pattern MPT may be located at the same layer as the gate electrode GT, and may be located adjacent to the oxide semiconductor layer OL.

The fifth insulation layer 50 may be located on the fourth insulation layer 40, and may cover the gate electrode GT and the conductive pattern MPT. The sixth insulation layer 60 may be located on the fifth insulation layer 50.

Referring to FIG. 7, a first signal contact hole OCNT1 and a second signal contact hole OCNT2 that pass through the fourth to sixth insulation layers 40, 50, and 60 may be defined in the display panel DP. The first signal contact hole OCNT1 and the second signal contact hole OCNT2 may be formed to expose at least a portion of the oxide semiconductor layer OL. The first signal contact hole OCNT1 may be formed to expose a portion of the first area DE of the oxide semiconductor layer OL, and the second signal contact hole OCNT2 may be formed to expose a portion of the second area SE of the oxide semiconductor layer OL.

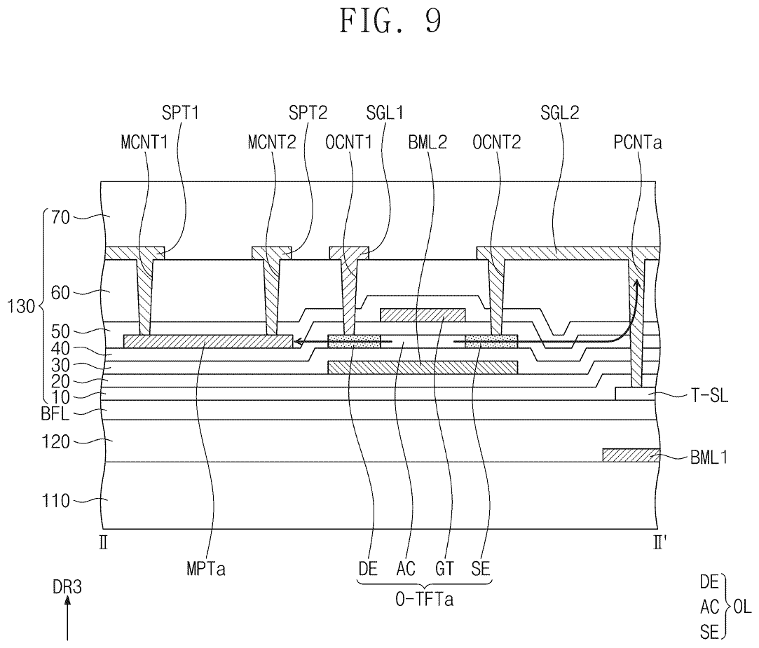

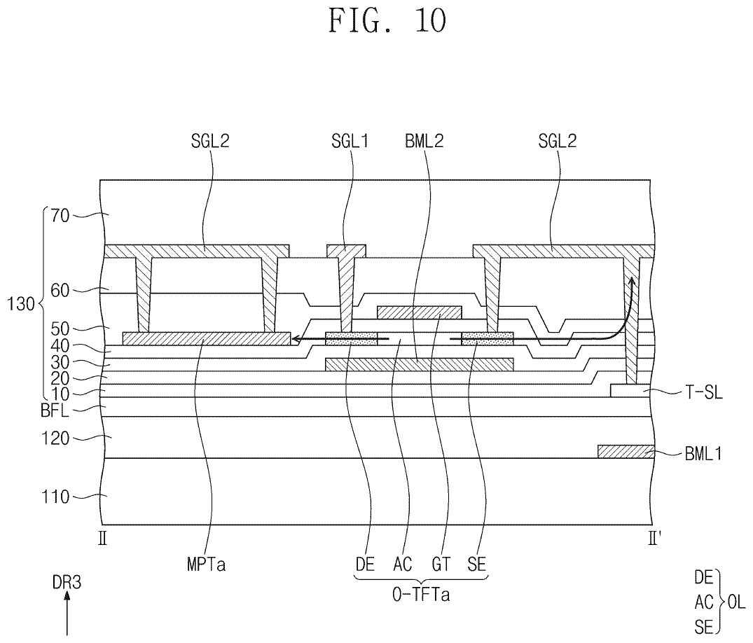

According to one or more embodiments of the present disclosure, the first signal contact hole OCNT1, the second signal contact hole OCNT2, and the dummy through-hole PCNT may be formed after deposition up to the sixth insulation layer 60. After the first signal contact hole OCNT1, the second signal contact hole OCNT2, and the dummy through-hole PCNT are formed, a thermal activation process (annealing) may be performed. During the thermal activation process, a conductive pattern MPT that is located adjacent to the oxide semiconductor layer OL may adsorb hydrogen of the oxide semiconductor layer OL. After the thermal activation process of adsorbing hydrogen of the oxide semiconductor layer OL to the conductive pattern MPT, referring to FIGS. 9 and 10, a first signal electrode SGL1 may be formed in the first signal contact hole OCNT1, and a second signal electrode SGL2 may be formed in the second signal contact hole OCNT2.

A dummy through-hole PCNT that passes through the intermediate insulation layer ML and the fourth to sixth insulation layers 40, 50, and 60 may be defined in the display panel DP. The dummy through-hole PCNT may be defined to expose at least a portion of the dummy semiconductor pattern SL.

The dummy through-holes PCNT may be located adjacent to the oxide semiconductor layer OL. During the thermal activation process, dummy through-holes PCNT that are located adjacent to the oxide semiconductor layer OL may provide a passage, through which hydrogen of the oxide semiconductor layer OL may escape to the outside. As hydrogen of the oxide semiconductor layer OL escapes to the outside, a channel of the oxide semiconductor transistor O-TFTa may be formed relatively short, and the likelihood of a threshold voltage of the oxide semiconductor transistor O-TFTa being negatively shifted may be reduced or prevented. Accordingly, a reliability of the oxide semiconductor transistor O-TFTa and the first and second driving circuits 131 and 132 including the oxide semiconductor transistor O-TFTa may be improved.

After the thermal activation process is completed, the dummy through-holes PCNT may be filled with an organic material that is subsequently deposited. Accordingly, the dummy through-holes PCNT may be electrically floated.

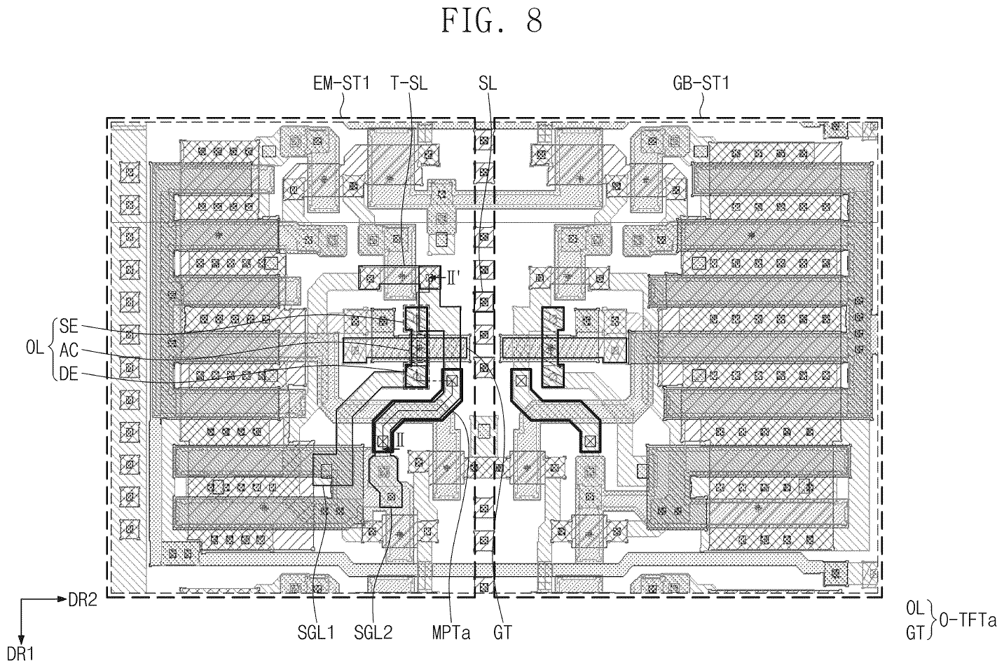

FIG. 8 is an enlarged plan view of a portion of a display panel DP according to one or more embodiments of the present disclosure. FIG. 9 is a cross-sectional view of a display panel DP taken along the line II-II′ of FIG. 8 according to one or more embodiments of the present disclosure. FIG. 10 is a cross-sectional view of a display panel DP taken along the line II-II′ of FIG. 8 according to one or more embodiments of the present disclosure.

FIG. 8 illustrates, by way of example, a (1-1)-th stage EM-ST1 of a first driving circuit 131 and a (2-1)-th stage GB-ST1 of a second driving circuit 132 as in FIG. 6, and the same configurations as those of FIG. 6 are denoted by the same reference numerals, and a repeated description thereof will be omitted.

Referring to FIGS. 8, 9, and 10, the display panel DP may include an oxide semiconductor transistor O-TFTa, a conductive pattern MPTa, a semiconductor pattern T-SL, a first signal electrode SGL1, and a second signal electrode SGL2.

The semiconductor pattern T-SL may be included in a low-temperature poly silicon semiconductor transistor that is located adjacent to the oxide semiconductor transistor O-TFTa. According to one or more embodiments of the present disclosure, the second signal electrode SGL2 may be electrically connected to the semiconductor pattern T-SL through a contact hole PCNTa that is formed to expose at least a portion of the semiconductor pattern T-SL.

The conductive pattern MPTa may be located on a fourth insulation layer 40. A fifth insulation layer 50 may be located on the fourth insulation layer 40, and may cover the conductive pattern MPTa. The sixth insulation layer 60 may be located on the fifth insulation layer 50.

Unlike those of FIGS. 6 and 7, the conductive pattern MPTa may have a wiring line shape. Accordingly, a third signal contact hole MCNT1 and a fourth signal contact hole MCNT2 that passes through the fifth to sixth insulation layers 50 and 60 may be defined in the display panel DP.

The signal contact hole MCNT1 and the fourth signal contact hole MCNT2 may be formed to expose at least a portion of the conductive pattern MPTa. The third signal contact hole MCNT1 may be formed at one end of the conductive pattern MPTa, which is relatively distant from the oxide semiconductor layer OL, and the fourth signal contact hole MCNT2 may be formed at an opposite end of the conductive pattern MPTa, which is relatively close to the oxide semiconductor layer OL. In this case, it may be formed by changing an existing wiring line to a conductive pattern MPTa, or a conductive pattern MPTa in the form a new wiring line may be additionally formed instead of the existing wiring line.

The first signal electrode SGL1 and the second signal electrode SGL2 may be located on the sixth insulation layer 60. Accordingly, the first signal electrode SGL1 and the second signal electrode SGL2 may be located at the same layer, and the first signal electrode SGL1 and the second signal electrode SGL2 may be located at a different layer from the conductive pattern MPTa, the oxide semiconductor layer OL, and the semiconductor pattern T-SL.

The first signal electrode SGL1 may be connected to the first area DE of the oxide semiconductor layer OL through the first signal contact hole OCNT1 that passes through the fourth to sixth insulation layers 40, 50, and 60.

The signal electrode SGL2 may be connected to the second area SE of the oxide semiconductor layer OL through the second signal contact hole OCNT2 that passes through the fourth to sixth insulation layers 40, 50, and 60. The second signal electrode SGL2 may be connected to the semiconductor pattern T-SL through the contact hole PCNTa that passes through the first to sixth insulation layers 10, 20, 30, 40, 50, and 60. Furthermore, the second signal electrode SGL2 may also be electrically connected to the conductive pattern MPTa through the third signal contact hole MCNT1 and the fourth signal contact hole MCNT2 that pass through the fifth to sixth insulation layers 50 and 60.

In one or more embodiments of the present disclosure, referring to FIG. 9, the second signal electrode SGL2 may include a first signal pattern SPT1 and a second signal pattern SPT2. The first signal pattern SPT1 may be electrically connected to one end of the conductive pattern MPTa through the third signal contact hole MCNT1. The second signal pattern SPT2 may be electrically connected to an opposite end of the conductive pattern MPTa through the fourth signal contact hole MCNT2.

The first signal pattern SPT1 and the second signal pattern SPT2 may be spaced apart from each other. When viewed on a plane, the first signal pattern SPT1 and the second signal pattern SPT2 may not overlap a portion of the conductive pattern MPTa.

In one or more embodiments of the present disclosure, referring to FIG. 10, the first signal pattern SPT1 and the second signal pattern SPT2 of the second signal electrode SGL2 may be connected to each other on the same layer. When viewed on plane/in a plan view, the entire second signal electrode SGL2 and the entire conductive pattern MPTa may overlap each other. Accordingly, while the second signal electrode SGL2 and the wiring line-shaped conductive pattern MPTa in FIG. 9 are formed in the form of a single layer, the second signal electrode SGL2 and the wiring line-shaped conductive pattern MPTa in FIG. 10 may be formed in the form of a multi-layer.

Referring to FIGS. 8, 9, and 10, the conductive pattern MPTa may be located adjacent to the oxide semiconductor layer OL, and hydrogen of the oxide semiconductor layer OL may be adsorbed to the conductive pattern MPTa. The contact hole PCNTa is also located adjacent to the oxide semiconductor layer OL, and may provide a passage, through which hydrogen of the oxide semiconductor layer OL may escape to the outside. As hydrogen of the oxide semiconductor layer OL escapes to the outside, a channel of the oxide semiconductor transistor O-TFTa may be formed to be relatively short, and a likelihood of a threshold voltage of the oxide semiconductor transistor O-TFTa being negatively shifted may be reduced or prevented. Accordingly, a reliability of the oxide semiconductor transistor O-TFTa and the first and second driving circuits 131 and 132 including the oxide semiconductor transistor O-TFTa may be improved.

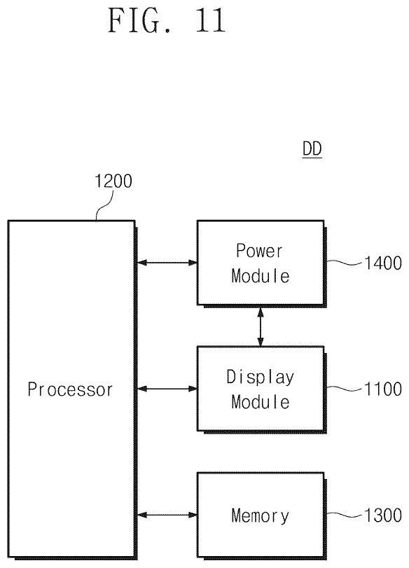

FIG. 11 is a block diagram of an electronic device according to one or more embodiments. Referring to FIG. 11, an electronic device DD according to one or more embodiments may include a display module 1100, a processor 1200, a memory 1300, and a power module 1400. The electronic device according to one or more embodiments may include a display device, and may further include modules or devices having additional functions in addition to the display device.

The processor 1200 may include at least one of a central processing unit (CPU), an application processor (AP), a graphic processing unit (GPU), a communication processor (CP), an image signal processor (ISP), and a controller. The processor 1200 may correspond to the driving controller 11 illustrated in FIG. 1.

The memory 1300 may store data information necessary for the operation of the processor 1200 or the display module 1100. When the processor 1200 executes an application stored in the memory 1300, an image data signal and/or an input control signal is transmitted to the display module 1100, and the display module 1100 can process the received signal and output image information through a display screen.

The power module 1400 may include a power supply module such as a power adapter or a battery device, and a power conversion module that converts the power supplied by the power supply module to generate power necessary for the operation of the electronic device DD.

At least one of the components of the electronic device DD described above may be included in the display device according to the embodiments described above. In addition, some of the individual modules functionally included in one module may be included in the display device, and other parts may be provided separately from the display device. For example, the display device may include the display module 1100, and the processor 1200, the memory 1300, and the power module 1400 may be provided in the form of other devices within the electronic device DD other than the display device.

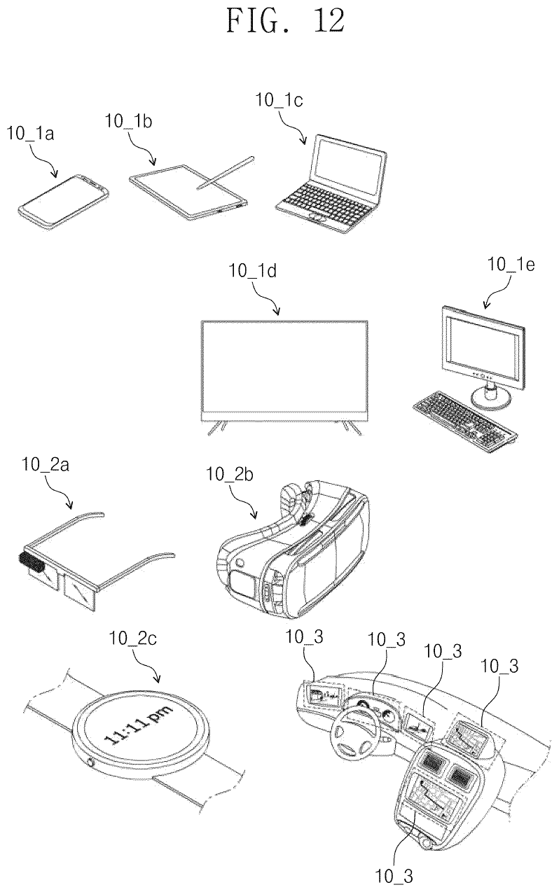

FIG. 12 is a schematic diagram of an electronic device according to various embodiments. Referring to FIG. 12, various electronic devices to which a display device according to the embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (Center Information Display) and a room mirror display placed on a dashboard, center fascia, and dashboard of an automobile.

The display panel and electronic device having the same according to embodiments of the present disclosure may absorb hydrogen that is generated from an oxide semiconductor layer by a conductive pattern that is adjacent to an oxide semiconductor layer. In this case, the oxide semiconductor layer may be dehydrogenated sufficiently, and a hydrogen concentration of the oxide semiconductor layer may be reduced. Accordingly, a degree, to which a threshold voltage of an oxide semiconductor transistor is negatively shifted, may be reduced or the threshold voltage may be positively shifted. As a result, a leakage due to negative shift of the oxide semiconductor transistor may be reduced or eliminated, and the reliability of the oxide semiconductor transistor and driving circuits may be improved.

Although the present disclosure has been described with reference to the embodiments, it will be appreciated by an ordinary skilled in the art, to which the present disclosure pertains, that the present disclosure may be modified and changed within the scope of the appended claims without departing from the spirits and technical field of the present disclosure. Therefore, the technical scope of the present disclosure should not be limited to the detailed description of the specification, but should be determined by the claims, with functional equivalents thereof to be included therein.

What is claimed is:

1. A display panel comprising:
a first driving circuit comprising first stages arranged along a first direction;
a second driving circuit comprising second stages arranged along the first direction; and
at least one clock line between the first driving circuit and the second driving circuit, and extending along the first direction,
wherein the first stages and the second stages comprise:
an oxide semiconductor transistor comprising an oxide semiconductor layer, and a gate electrode overlapping portions of the oxide semiconductor layer; and
a conductive pattern adjacent to the oxide semiconductor transistor, and at a same layer as the gate electrode.

2. The display panel of claim 1, wherein the oxide semiconductor layer comprises a first area, an active area, and a second area spaced apart from the first area with the active area therebetween, and
wherein the display panel further comprises a first signal electrode electrically connected to the first area, and a second signal electrode electrically connected to the second area.

3. The display panel of claim 2, wherein the conductive pattern comprises an electrically floated island shape.

4. The display panel of claim 3, wherein the conductive pattern partially surrounds at least a portion of the first area in plan view.

5. The display panel of claim 2, wherein the conductive pattern is electrically connected to the second signal electrode.

6. The display panel of claim 5, wherein the second signal electrode comprises:
a first signal pattern electrically connected to one end of, and at a different layer from, the conductive pattern; and
a second signal pattern spaced from the first signal pattern, and electrically connected to an opposite end of, and at a different layer from, the conductive pattern.

7. The display panel of claim 5, wherein the conductive pattern entirely overlaps the second signal electrode in plan view.

8. The display panel of claim 1, wherein the at least one clock line comprises a first clock line, and a second clock line spaced apart from the first clock line in a second direction crossing the first direction.

9. The display panel of claim 8, further comprising:
a dummy semiconductor pattern at a different layer from the oxide semiconductor layer; and
an intermediate insulation layer covering the dummy semiconductor pattern, and defining a dummy through-hole adjacent to the oxide semiconductor layer and exposing at least a portion of the dummy semiconductor pattern.

10. The display panel of claim 9, wherein the dummy semiconductor pattern comprises a low-temperature poly silicon semiconductor.

11. The display panel of claim 9, wherein the oxide semiconductor layer is above the intermediate insulation layer.

12. The display panel of claim 9, wherein the dummy semiconductor pattern is provided in plural, the dummy semiconductor patterns being spaced apart along the first direction.

13. The display panel of claim 12, wherein the dummy semiconductor patterns are between the first clock line and the second clock line in plan view.

14. The display panel of claim 1, wherein the conductive pattern comprises titanium.

15. An electronic device comprising:
a display panel and a processor that drives the display panel, the display panel comprising:
pixels;
a first driving circuit electrically connected to the pixels, and comprising a first stage;
a second driving circuit electrically connected to the pixels, and comprising a second stage; and
a dummy semiconductor pattern between the first stage and the second stage in plan view,
wherein the first stage and the second stage comprise an oxide semiconductor transistor comprising an oxide semiconductor layer and a gate electrode, and a conductive pattern, and
wherein the conductive pattern and the dummy semiconductor pattern are adjacent to the oxide semiconductor layer in plan view.

16. The electronic device of claim 15, further comprising an intermediate insulation layer covering the dummy semiconductor pattern, and defining a dummy through-hole adjacent to the oxide semiconductor layer and exposing at least a portion of the dummy semiconductor pattern,
wherein the dummy semiconductor pattern comprises a low-temperature poly silicon semiconductor, and
wherein the oxide semiconductor layer is above the intermediate insulation layer.

17. The electronic device of claim 15, wherein the conductive pattern comprises an electrically floated island shape, and partially surrounds at least a portion of the oxide semiconductor layer in plan view.

18. The electronic device of claim 15, wherein the oxide semiconductor layer comprises a first area, an active area, and a second area spaced apart from the first area with the active area therebetween, and
wherein the display panel further comprises a first signal electrode electrically connected to the first area, and a second signal electrode electrically connected to the second area and electrically connected to the conductive pattern.

19. The electronic device of claim 18, wherein the second signal electrode comprises:
a first signal pattern electrically connected to one end of the conductive pattern, and at a different layer from the conductive pattern; and
a second signal pattern electrically connected to an opposite end of the conductive pattern, spaced from the first signal pattern, and at a different layer from the conductive pattern.

20. The electronic device of claim 18, wherein the conductive pattern entirely overlaps the second signal electrode in plan view.
